(19) United States
(12) Patent Application Publication
(10) Pub. No.: US 2025/0366124 A1
(43) Pub. Date: Nov. 27, 2025

(54) SEMICONDUCTOR DEVICE HAVING NANOSHEET TRANSISTOR AND METHODS OF FABRICATION THEREOF

(71) Applicant: TAIWAN SEMICONDUCTOR MANUFACTURING COMPANY, LTD., Hsinchu (TW)

(72) Inventors: Zheng Hui LIM, Hsinchu (TW); Ji-Yin TSAI, Hsinchu (TW); Ming-Hua YU, Hsinchu (TW); Chii-Horng LI, Hsinchu (TW)

(21) Appl. No.: 19/294,310

(22) Filed: Aug. 8, 2025

Related U.S. Application Data
(63) Continuation of application No. 18/619,324, filed on Mar. 28, 2024.
(60) Provisional application No. 63/596,679, filed on Nov. 7, 2023.

(51) Int. Cl. H10D 64/01; H10D 30/01; H10D 30/43; H10D 30/67; H10D 62/10; H10D 62/13; H10D 84/01; H10D 84/03; H10D 84/83

(52) U.S. Cl. CPC H10D 64/017; H10D 30/014; H10D 30/43; H10D 30/6735; H10D 30/6757; H10D 62/116; H10D 62/121; H10D 62/151; H10D 84/0128; H10D 84/013; H10D 84/038; H10D 84/83

(57) ABSTRACT

Method for forming semiconductor device structure includes forming a sacrificial layer between first and second stacks of layers, the first stack of layers comprises first and second semiconductor layers alternatingly stacked, and the second stack of layers comprises third and fourth semiconductor layers alternatingly stacked, wherein the sacrificial layer comprises a semiconductor metal oxide, forming a sacrificial gate structure over portion of the second stack of layers, removing portions of the first and second stack of layers not covered by the sacrificial gate structure, removing the sacrificial layer to form cavity, filling the cavity with a dielectric to form an isolation layer, and forming first and second source/drain features on opposing sides of sacrificial gate structure, wherein the first source/drain feature is disposed below the second source/drain feature, and the first and second source/drain features are in contact with the isolation layer, first semiconductor layers, and third semiconductor layers.

This application is a continuation application of U.S. patent application Ser. No. 18/619,324 filed Mar. 28, 2024, which claims priority to U.S. Provisional Application Ser. No. 63/596,679 filed Nov. 7, 2023, which is incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down presents new challenge.

In pursuit of higher device density, higher performance, and lower costs, challenges from both fabrication and design issues have resulted in the development of three-dimensional designs, such as a multi-gate field effect transistor (FET), including a nanoshect FET. In a nanosheet FET, all side surfaces of the channel are surrounded by the gate electrode, which allows for fuller depletion in the channel and results in less short-channel effects and better gate control. As transistor dimensions are continually scaled down, further improvements of the nanosheet FET are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-12 are perspective views of various stages of manufacturing a semiconductor device structure in accordance with some embodiments.

FIGS. 13A-25A and 31A-32A are cross-sectional side views of various stages of manufacturing the semiconductor device structure taken along cross-section A-A of FIG. 12, in accordance with some embodiments.

FIGS. 13B-25B and 31B-32B are cross-sectional side views of various stages of manufacturing the semiconductor device structure taken along cross-section B-B of FIG. 12, in accordance with some embodiments.

FIGS. 13C-25C and 31C-32C are cross-sectional side views of various stages of manufacturing the semiconductor device structure taken along cross-section C-C of FIG. 12, in accordance with some embodiments.

FIG. 13D illustrates an enlarged view of a portion the stack of semiconductor layers in accordance with some embodiments.

FIG. 14A-1 illustrates an enlarged view of a portion of the semiconductor device structure showing the profile of the cavity, in accordance with some embodiments.

FIGS. 26-30 are enlarged views of a region of FIG. 25B showing various stages of manufacturing the semiconductor device structure in accordance with some embodiments.

FIG. 31D is an enlarged view of a portion of the semiconductor device structure showing the first and second nanosheet transistors.

FIG. 31D-1 is an enlarged view of a region of the semiconductor device structure shown in FIG. 31D.

FIG. 31D-2 is an enlarged view of a region of the semiconductor device structure shown in FIG. 31D, in accordance with the embodiment shown in FIG. 14A-1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

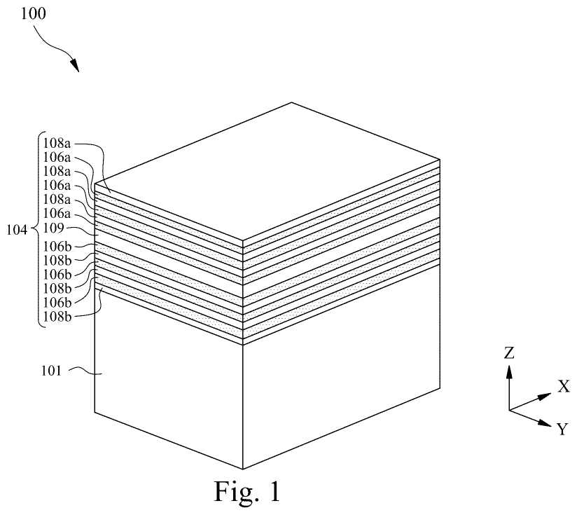

FIGS. 1-32C show exemplary processes for manufacturing a semiconductor device structure 100 according to embodiments of the present disclosure. It is understood that additional operations can be provided before, during, and after processes shown by FIGS. 1-32C, and some of the operations described below can be replaced or eliminated, for additional embodiments of the method. The order of the operations/processes is not limiting and may be interchangeable.

FIGS. 1-12 are perspective views of various stages of manufacturing a semiconductor device structure 100 in accordance with some embodiments. As shown in FIG. 1, a semiconductor device structure 100 includes a stack of semiconductor layers 104 formed over a substrate 101. The substrate 101 may be a semiconductor substrate. The substrate 101 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In one embodiment, the substrate 101 is made of silicon. In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include one or more buffer layers (not shown) on the surface of the substrate 101. The buffer layers can serve to gradually change the lattice constant from that of the substrate to that of the source/drain (S/D) regions to be grown on the substrate 101. The buffer layers may be formed from epitaxially grown single crystalline semiconductor materials such as, but not limited to Si, Ge, germanium tin (GeSn), SiGe, GaAs, InSb, GaP, GaSb, InAlAs, InGaAs, GaSbP, GaAsSb, GaN, GaP, and InP. In one embodiment, the substrate 101 includes SiGe buffer layers epitaxially grown on the silicon substrate 101. The germanium concentration of the SiGe buffer layers may increase from 30 atomic percent germanium for the bottom-most buffer layer to 70 atomic percent germanium for the top-most buffer layer.

The substrate 101 may include various regions that have been doped with impurities (e.g., dopants having p-type or n-type conductivity). Depending on circuit design, the dopants may be, for example boron for an n-type field effect transistors (NFET) and phosphorus for a p-type field effect transistors (PFET).

The stack of semiconductor layers 104 includes semiconductor layers made of different materials to facilitate formation of nanosheet channels in a multi-gate device, such as nanosheet channel FETs. In some embodiments, the stack of semiconductor layers 104 includes first semiconductor layers 106a and 106b (collectively referred to as 106) and second semiconductor layers 108a and 108b (collectively referred to as 108). In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GalnP, GalnAsP, or any combinations thereof.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

In some embodiments, the semiconductor device structure 100 includes a complementary FET (CFET) in which two or more nanosheet FETs are vertically stacked on top of one another. In such a case, the first semiconductor layers 106 can include channels for the two or more nanosheet FETs. In the embodiment shown in FIG. 1, for example, the first semiconductor layers 106a may define the channels of a first FET, such as a n-type FET (N-FET), and the first semiconductor layers 106b may define the channels of a second FET, such as a p-type FET (P-FET). The thickness of the first semiconductor layers 106 is chosen based on device performance considerations. In some embodiments, each first semiconductor layer 106 has a thickness ranging from about 3 nanometers (nm) to about 10 nm. The second semiconductor layers 108 may eventually be removed and serve to define spaces for a gate stack to be formed therein. Likewise, each second semiconductor layer 108 may have a thickness that is equal, less, or greater than the thickness of the first semiconductor layer 106, depending on device performance considerations. In one aspect, each second semiconductor layer 108 (e.g., 108a and 108b) has a thickness that is equal to the thickness of the first semiconductor layer 106 (e.g., 106a and 106b).

In various embodiments, a sacrificial layer 109 is formed between the first semiconductor layer 106a in the first FET (e.g., n-channel FET) and the first semiconductor layer 106b in the second FET (e.g., p-channel FET). The sacrificial layer 109 is to be replaced with a dielectric material at a later stage and form an isolation layer for isolation purpose. The material of the sacrificial layer 109 is selected so that it can grow on silicon (or the material used by the immediately adjacent layer, e.g., the first semiconductor layer 106b) with minimum or no lattice mismatch between the sacrificial layer 109 and the neighboring layers (e.g., first semiconductor layer 106a and/or 106b). As a result, dislocation issues that may occur as a result of lattice mismatch between the sacrificial layer 109 and the neighboring layers are mitigated. The material for the sacrificial layer 109 should also have a high etch selectivity with respect to silicon (or the material used by the neighboring layers) so that it can be easily removed at a later stage without substantially affecting the neighboring layers.

In some embodiments, the sacrificial layer 109 is made of semiconductor metal oxides, such as alkaline earth titanate. Suitable materials may include, but are not limited to, strontium titanate (SrTiO₃), barium titanate (BaTiO₃), barium strontium titanate (BaSrTiO₃), lanthanum titanate (LaTiO₃), or the like. The semiconductor metal oxides may be grown on the first semiconductor layer 106 by any suitable deposition process. In some embodiments, the semiconductor metal oxides is grown on the first semiconductor layer 106 (e.g., first semiconductor layer 106b) by a molecular beam epitaxy (MBE). In embodiments where SrTiO₃ is desired, a first metal solid source containing Sr (e.g., elemental Sr) and a second metal solid source containing Ti (e.g., elemental Ti or titanium tetra isopropoxide [Ti(OC₃H₇) 4 or TTIP]) may be supplied into an MBE chamber, in which the first metal source and the second metal solid source are heated up and evaporated onto the first semiconductor layer 106 (e.g., first semiconductor layer 106b). Oxygen gas may be supplied into the MBE chamber during the growth. The sacrificial layer 109 may be grown on the first semiconductor layer 106b at a chamber pressure of about 10-10 Torr (i.e., ultrahigh vacuum) in a temperature range of about 400 degrees Celsius to about 800 degrees Celsius, for example about 500 degrees Celsius to about 700 degrees Celsius. If the temperature is greater than about 800 degrees Celsius, the deposited film may be relaxed too quickly. On the other hand, if the temperature is lower than about 400 degrees Celsius, the quality of the deposited film may be compromised (e.g., poly-crystalline or even amorphous). The sacrificial layer 109 deposited outside the above-mentioned temperature range may result in non-crystalline film. The growth rate may be in a range of about 1 nm/minute to about 3 nm/minute.

In some embodiments, the semiconductor metal oxides may be grown on the first semiconductor layer 106 (e.g., first semiconductor layer 106b) by a metal-organic chemical vapor deposition (MOCVD). In embodiments where SrTiO₃ is desired, a first metalorganic precursor containing Ti (e.g., titanium tetraisopropoxide (TPT)) and a second metalorganic precursor containing Sr (e.g., Sr(hfa)₂· tetraglyme, hfa=hexafluoroacetylacetonate) may be supplied to and heated at respective reactor source zones of an MOCVD reactor. Each of the first and second metalorganic precursors is transported to a reaction zone using a carrier gas such as argon. Oxygen bubbled through de-ionized water may serve as a reactant gas. The total pressure of the MOCVD reactor may be in a range of about 1 Torr to about 20 Torr, such as about 4 Torr, and the growth temperature of the MOCVD reactor may be in a range of about 700 degrees Celsius to about 900 degrees Celsius, such as about 800 degrees Celsius. The total reactor pressure and the oxygen partial pressure may be controlled by the set flow rates. The total flow rate of the metalorganic precursors may be about 100 sccm to about 150 sccm, and the flow rate of the oxygen may be about 40 sccm to about 60 sccm. The growth rate may be in a range of about 4 nm/minute to about 12 nm/minute.

In some embodiments, the semiconductor metal oxides may be grown on the first semiconductor layer 106 (e.g., first semiconductor layer 106b) by an atomic layer deposition (ALD), such as a plasma-assisted ALD process. In embodiments where SrTiO₃ is desired, the first semiconductor layer (e.g., first semiconductor layer 106b) may be exposed to deposition cycles comprising pulses of a first metal precursor containing Sr (e.g., strontium bis(tri-isopropylcyclopentadienyl) (Sr(CsiPr₃H₂)₂)), a second metal precursor containing Ti (e.g., titanium tetraisopropoxide (Ti(OPr)₄), and an oxidizer using water vapor in an ALD chamber. The pulsing sequence may be repeated as (Sr(CsiPr₃H₂)₂)—H₂O—(Ti(OiPr)₄)—H₂O, and may be performed at a temperature of about 225 degrees Celsius to about 325 degrees Celsius. An purging gas using inert gas and vacuum pumping may be applied between reactant exposures. The deposition rate may be in a range of about 0.5 Å per cycle to about 1.5 Å per cycle.

In any case, the sacrificial layer 109 may have a greater thickness than the thickness of the first or second semiconductor layers to enhance isolation between the first FET and the second FET at a later stage. The thickness of the sacrificial layer 109 may be about 1.5 to about 3 times thicker than the first semiconductor layer 106 (e.g., 106a and 106b) or the second semiconductor layer 108 (e.g., 108a and 108b). In some embodiments, the sacrificial layer 109 has a thickness of about 3 nm to about 50 nm. If the deposited thickness is less than about 3 nm, it may be difficult to grow substantial amount of the sacrificial layer 109 in the later process, and the effectiveness of isolation may be reduced. On the other hand, if the deposited thickness is greater than about 50 nm, the sacrificial layer 109 may be relaxed.

While six first semiconductor layers 106 and six second semiconductor layers 108 are alternately arranged as illustrated in FIG. 1, it can be appreciated that any number of first and second semiconductor layers 106, 108 can be formed in the stack of semiconductor layers 104, depending on the predetermined number of nanosheet channels needed for each FET of the semiconductor device structure 100.

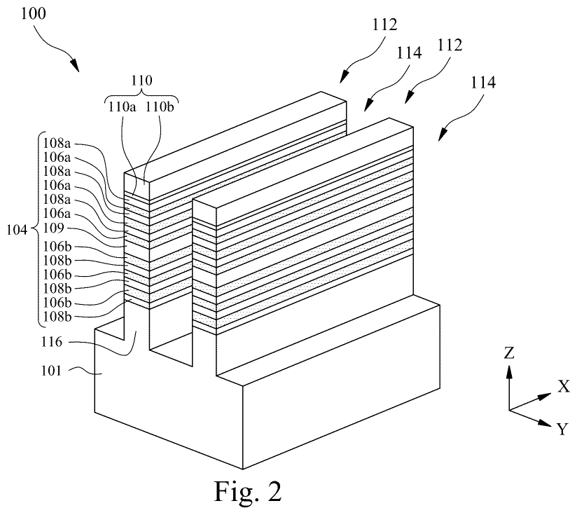

FIG. 2 is a perspective view of one of the various stages of manufacturing the semiconductor device structure 100, in accordance with some embodiments. As shown in FIG. 2, fin structures 112 are formed from the stack of semiconductor layers 104. Each fin structure 112 has an upper portion including the semiconductor layers 106, 108, a well portion 116 formed from the substrate 101, and a portion of a mask structure 110. The mask structure 110 is formed over the stack of semiconductor layers 104 prior to forming the fin structures 112. The mask structure 110 may include an oxygen-containing layer 110a and a nitrogen-containing layer 110b. The oxygen-containing layer 110a may be a pad oxide layer, such as a SiO₂ layer. The nitrogen-containing layer 110b may be a pad nitride layer, such as Si₃N₄. The mask structure 110 may be formed by any suitable deposition process, such as chemical vapor deposition (CVD) process.

The fin structures 112 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin structures 112 by etching the stack of semiconductor layers 104 and the substrate 101. The etch process can include dry etch, wet etch, reactive ion etch (RIE), and/or other suitable processes. While two fin structures 112 are shown, the number of the fin structures is not limited to two.

In some embodiments, the fin structures 112 may be fabricated using suitable processes including photolithography and etch processes. The photolithography process may include forming a photoresist layer (not shown) over the mask structure 110, exposing the resist to a pattern, performing post-exposure bake processes, and developing the resist to form a patterned resist. In some embodiments, patterning the resist to form the patterned resist may be performed using an electron beam (e-beam) lithography process. The patterned resist may then be used to protect regions of the substrate 101, and layers formed thereupon, while an etch process forms trenches 114 in unprotected regions through the mask structure 110, the stack of semiconductor layers 104, and into the substrate 101, thereby leaving the extending fin structures 112. The trenches 114 may be etched using a dry etch (e.g., RIE), a wet etch, and/or combination thereof.

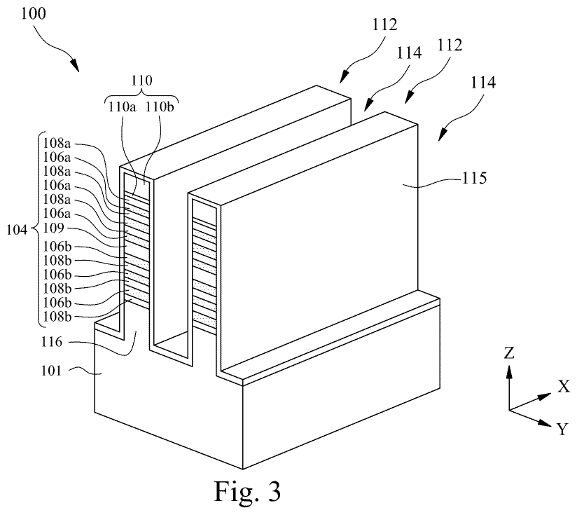

In FIG. 3, a liner 115 is formed over the substrate 101 and the fin structures 112. The liner 115 may be formed of a semiconductor material, such as Si. In some embodiments, the liner 115 is made of the same material as the substrate 101. The liner 115 may be a conformal layer formed by any suitable process, such as an atomic layer deposition (ALD) process. The term “conformal” may be used herein for ease of description upon a layer having substantial same thickness over various regions.

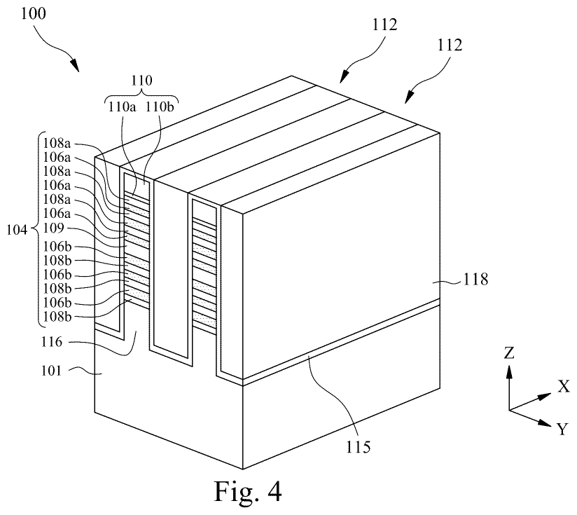

In FIG. 4, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed to expose the top of the fin structures 112. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

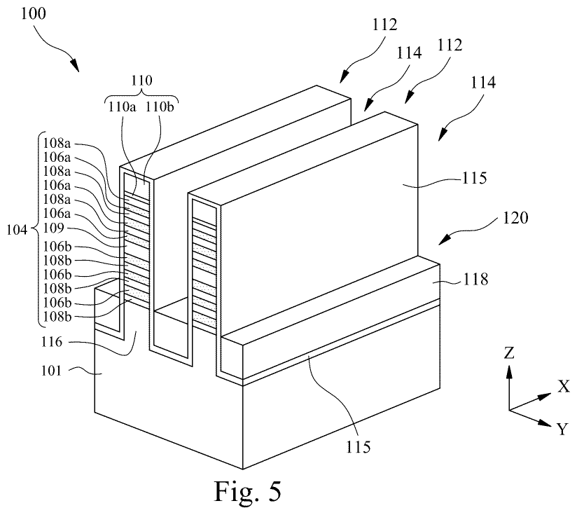

In FIG. 5, the insulating material 118 is recessed to form an isolation region 120. The recess of the insulating material 118 exposes portions of the fin structures 112. The recess of the insulating material 118 reveals the trenches 114 between the neighboring fin structures 112. The isolation region 120 may be formed using a suitable process, such as a dry etching process, a wet etching process, or a combination thereof. A top surface of the insulating material 118 may be level with or below a surface of the second semiconductor layers 108 (e.g., 108b) in contact with the well portion 116.

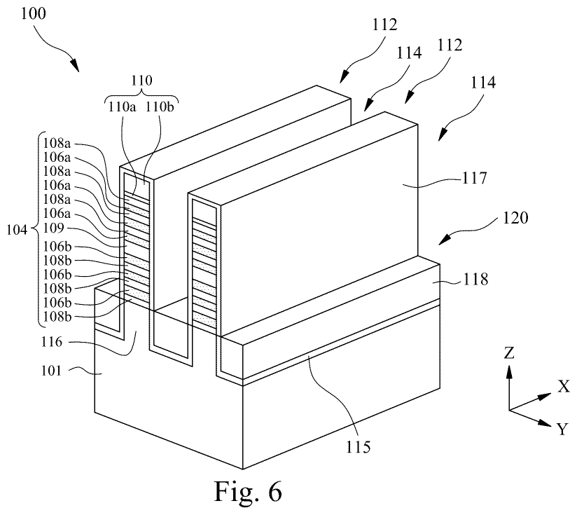

In FIG. 6, a cladding layer 117 is formed on the exposed surface of the liner 115 (FIG. 5). In some embodiments, the liner 115 may be diffused into the cladding layer 117 during the formation of the cladding layer 117, resulting in the cladding layer 117 in contact with the stack of semiconductor layers 104. The cladding layer 117 may be or include a semiconductor material, which allows the cladding layer 117 to grow on semiconductor materials but not on dielectric materials. For example, the cladding layer 117 may be SiGe and is grown on the Si of the liner 115 but not on the dielectric material of the insulating material 118. In some embodiments, the cladding layer 117 may be formed by first forming a semiconductor layer on the liner 115 and the insulating material 118. An etch process is then performed to remove portions of the semiconductor layer formed on the insulating material 118. In some embodiments, the cladding layer 117 and the second semiconductor layers 108 include the same material having the same etch selectivity. For example, the cladding layer 117 and the second semiconductor layers 108a, 108b may be or include SiGe. The cladding layer 117 and the second semiconductor layers 108a, 108b may be removed subsequently to create space for the gate electrode layer.

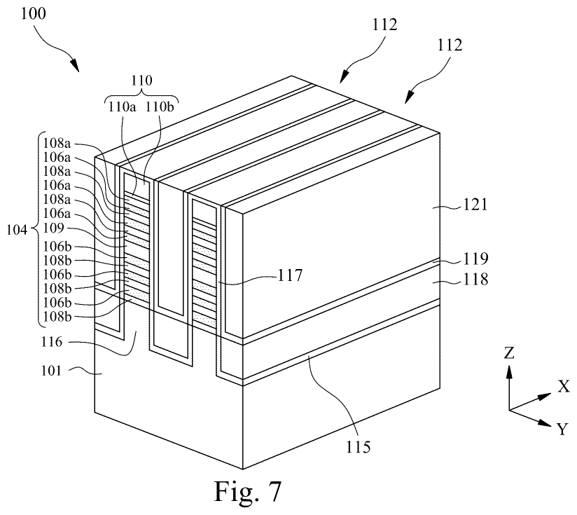

In FIG. 7, a liner 119 is formed on the cladding layer 117 and the top surface of the insulating material 118. The liner 119 may include a low-k dielectric material (e.g., a material having a k value lower than 7), such as SiO₂, SiN, SiCN, SiOC, or SiOCN. The liner 119 may be formed by a conformal process, such as an ALD process. The liner 119 may function as a shell to protect a flowable oxide material to be formed in the trenches 114 (FIG. 6) during subsequent removal of the cladding layer 117.

A dielectric material 121 is formed in the trenches 114 (FIG. 6) and on the liner 119, as shown in FIG. 7. The dielectric material 121 may be an oxygen-containing material, such as an oxide, formed by FCVD. The oxygen-containing material may have a K value less than about 7, for example less than about 3. A planarization process, such as a CMP process, may be performed to remove portions of the liner 119 and the dielectric material 121 formed over the fin structures 112. The portion of the cladding layer 117 disposed on the nitrogen-containing layer is exposed after the planarization process.

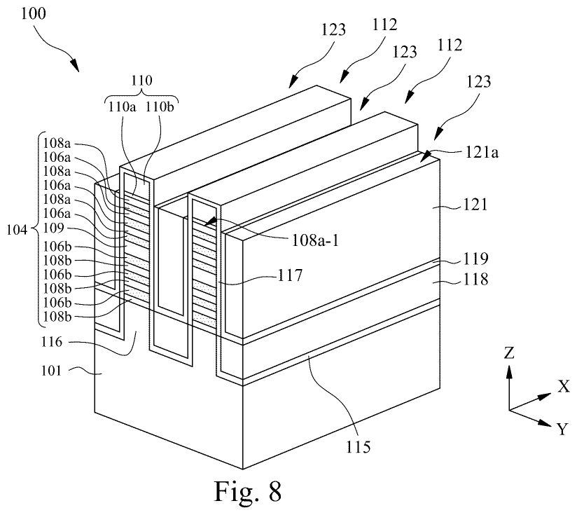

In FIG. 8, the liner 119 and the dielectric material 121 are recessed to the level of the topmost second semiconductor layer 108a. For example, in some embodiments, after the recess process, the dielectric material 121 may include a top surface 121a that is substantially level with a top surface 108a-1 of the topmost second semiconductor layer 108a. The top surface 108a-1 of the topmost second semiconductor layer 108a may be in contact with the mask structure 110, such as in contact with the oxygen-containing layer 110a. Likewise, the liner 119 may be recessed to the same level as the dielectric material 121. The recess of the liner 119 and the dielectric material 121 may be performed by any suitable process, such as dry etch, wet etch, or a combination thereof. The etch processes may be selective etch processes that do not remove the semiconductor material of the cladding layer 117. As a result of the recess process, trenches 123 are formed between the fin structures 112.

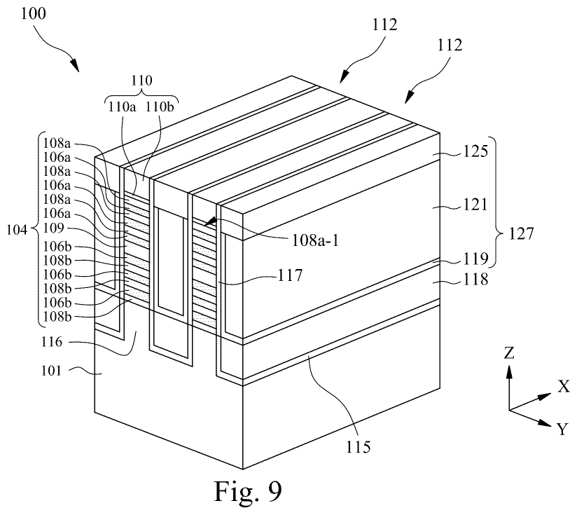

In FIG. 9, a dielectric material 125 is formed in the trenches 123 (FIG. 8) and on the dielectric material 121 and the liner 119. The dielectric material 125 may include SiO, SiN, SiC, SiCN, SION, SIOCN, AIO, AlN, AION, ZrO, ZrN, ZrAIO, HfO, or other suitable dielectric material. In some embodiments, the dielectric material 125 includes a high-k dielectric material (e.g., a material having a k value greater than 7). The dielectric material 125 may be formed by any suitable process, such as a CVD, PECVD, FCVD, or ALD process. A planarization process, such as a CMP process, is performed until the nitrogen-containing layer 110b of the mask structure 110 is exposed. The planarization process removes portions of the dielectric material 125 and the cladding layer 117 disposed over the mask structure 110. The liner 119, the dielectric material 121, and the dielectric material 125 together may be referred to as a dielectric feature 127. The dielectric feature 127 serves as a dielectric fin that separates adjacent source/drain (S/D) epitaxial features and adjacent gate electrode layers.

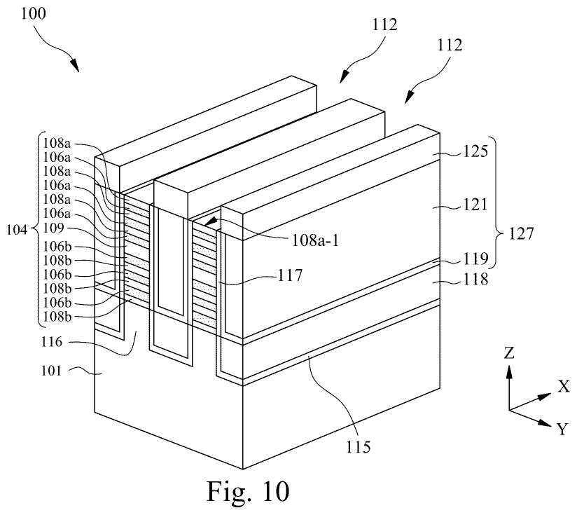

In FIG. 10, the cladding layers 117 are recessed, and the mask structures 110 are removed. The recess of the cladding layers 117 may be performed by any suitable process, such as dry etch, wet etch, or a combination thereof. The recess process may be controlled so that the remaining cladding layers 117 are substantially at the same level as the top surface 108a-1 of the topmost second semiconductor layer 108a in the stack of semiconductor layers 104. The etch process may be a selective etch process that does not remove the dielectric material 125.

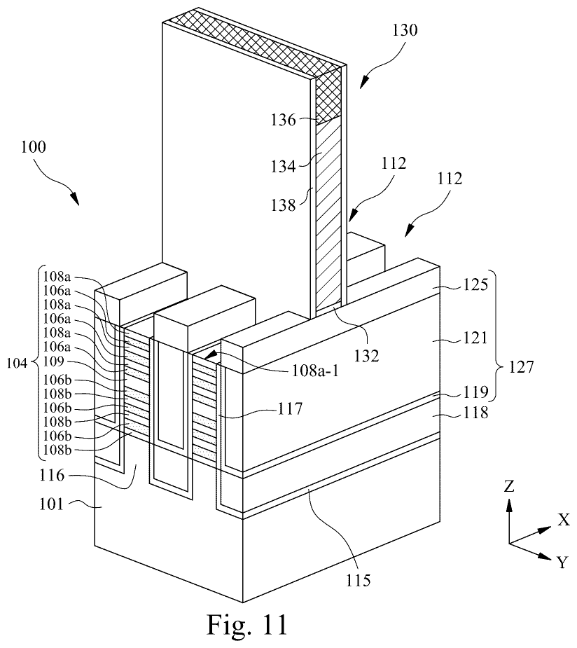

In FIG. 11, one or more sacrificial gate structures 130 are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, followed by pattern and etch processes.

By patterning the sacrificial gate structure 130, the stacks of semiconductor layers 104 of the fin structures 112 are partially exposed on opposite sides of the sacrificial gate structure 130. The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. While one sacrificial gate structure 130 is shown, two or more sacrificial gate structures 130 may be arranged along the X direction in some embodiments.

Next, gate spacers 138 are formed on sidewalls of the sacrificial gate structures 130. The gate spacers 138 may be formed by first depositing a conformal layer that is subsequently etched back to form sidewall gate spacers 138. For example, a spacer material layer can be disposed conformally on the exposed surfaces of the semiconductor device structure 100. Subsequently, anisotropic etch is performed on the spacer material layer using, for example, RIE. During the anisotropic etch process, most of the spacer material layer is removed from horizontal surfaces, such as the tops of the fin structures 112, the cladding layer 117, the dielectric material 125, leaving the gate spacers 138 on the vertical surfaces, such as the sidewalls of sacrificial gate structures 130. The gate spacer 138 may be made of a dielectric material such as silicon oxide, silicon nitride, silicon carbide, silicon oxynitride, SiCN, silicon oxycarbide, SiOCN, and/or combinations thereof.

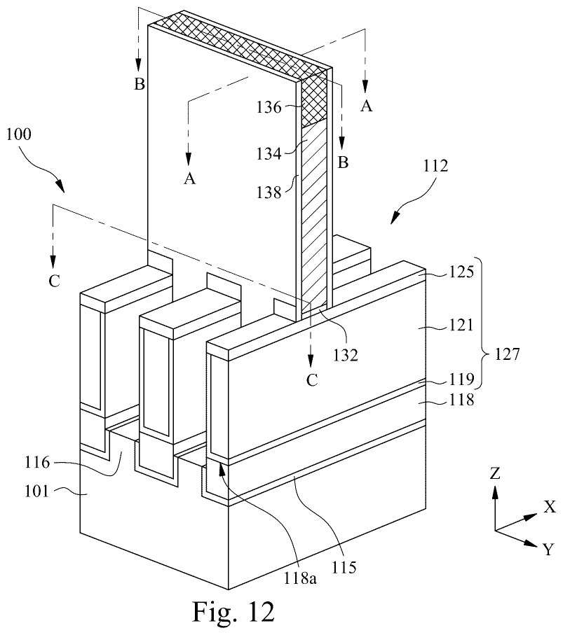

In FIG. 12, exposed portions of the fin structures 112, exposed portions of the cladding layers 117, and exposed portions of the dielectric material 125 not covered by the sacrificial gate structures 130 and the gate spacers 138 are selectively recessed by using one or more suitable etch processes. In some embodiments, exposed portions of the stacks of semiconductor layers 104 of the fin structures 112 are removed, exposing portions of the well portions 116. As shown in FIG. 12, the exposed portions of the fin structures 112 are recessed to a level at or below the top surface 118a of the insulating material 118. The recess processes may include an etch process that recesses the exposed portions of the fin structures 112 and the exposed portions of the cladding layers 117.

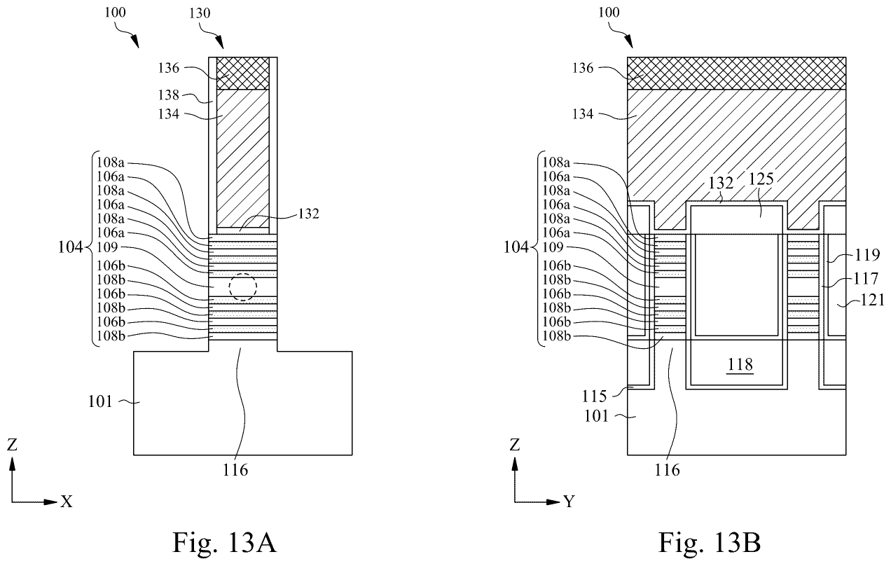

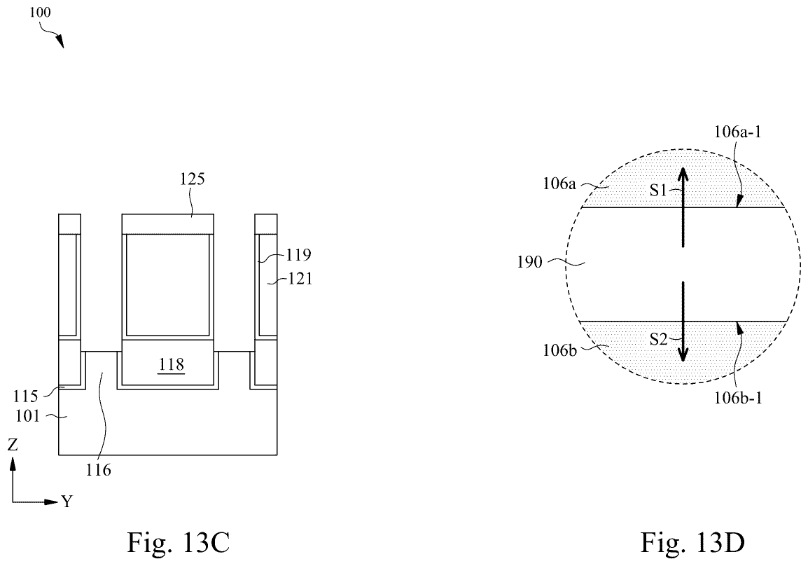

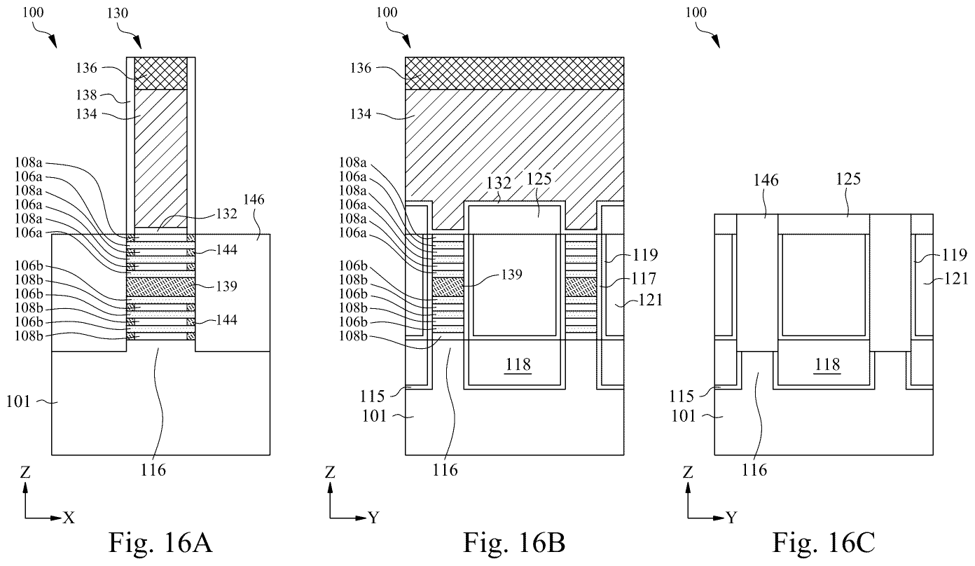

FIGS. 13A-25A and 31A-32A are cross-sectional side views of various stages of manufacturing the semiconductor device structure 100 taken along cross-section A-A of FIG. 12, in accordance with some embodiments. FIGS. 13B-25B and 31B-32B are cross-sectional side views of various stages of manufacturing the semiconductor device structure 100 taken along cross-section B-B of FIG. 12, in accordance with some embodiments. FIGS. 13C-25C and 31C-32C are cross-sectional side views of various stages of manufacturing the semiconductor device structure 100 taken along cross-section C-C of FIG. 12, in accordance with some embodiments. Cross-section A-A are in a plane of the fin structure 112 (FIG. 12) along the X direction. Cross-section B-B is in a plane perpendicular to cross-section A-A and is in the sacrificial gate structure 130 along the Y direction. Cross-section C-C is in a plane perpendicular to cross-section A-A and is in the S/D features 146 (FIG. 16A) along the Y-direction.

FIG. 13D illustrates an enlarged view of a portion the stack of semiconductor layers 104 in accordance with some embodiments. Various processes (cleaning, deposition, or etching processes etc.) performed after formation of the sacrificial layer 109 may cause the atoms in the sacrificial layer 109 to diffuse into the neighboring layers. In some embodiments, the atoms (e.g., alkaline elements Sr or Ti) in the sacrificial layer 109 may have a profile gradually changed along the thickness of the sacrificial layer 109, and the atoms may be further diffused into the first semiconductor layers 106a, 106b, respectively. In some embodiments, the atoms (e.g., alkaline elements Sr or Ti) are evenly distributed throughout the thickness of the sacrificial layer 109. In some embodiments, the atoms (e.g., alkaline elements Sr or Ti) in the sacrificial layer 109 are distributed to have a gradient profile after various processes. For example, the atoms in the sacrificial layer 109 may have a first element concentration at and/or near the center region of the sacrificial layer 109, and a second element concentration at and/or near an interface 106a-1, 106b-1 of the sacrificial layer 109 and the first semiconductor layers 106a, 106b, wherein the first element concentration is less than the second element concentration. The atoms are diffused into the neighboring layers (e.g., first semiconductor layers 106a, 106b) along arrows S1 and S2 and may also have a gradual gradient distribution. For example, the first semiconductor layer 106a may have a first element concentration at and/or near an interface 106a-1 of the sacrificial layer 109 and the first semiconductor layer 106a, and a second element concentration at and/or near the center region of the first semiconductor layer 106a, wherein the first element concentration is greater than the second element concentration. Likewise, the first semiconductor layer 106b may have a first element concentration at and/or near an interface 106b-1 of the sacrificial layer 109 and the first semiconductor layer 106b, and a second element concentration at and/or near the center region of the first semiconductor layer 106b, wherein the first element concentration is greater than the second element concentration.

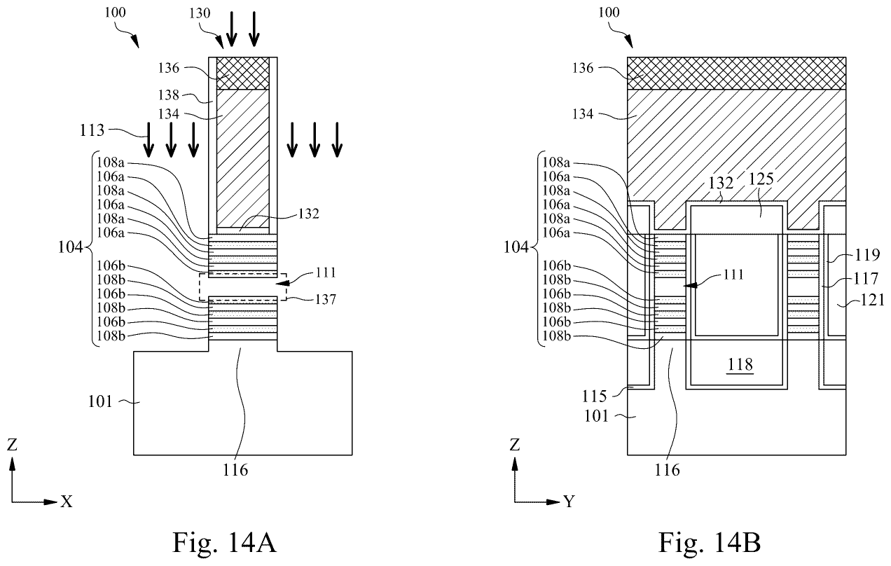

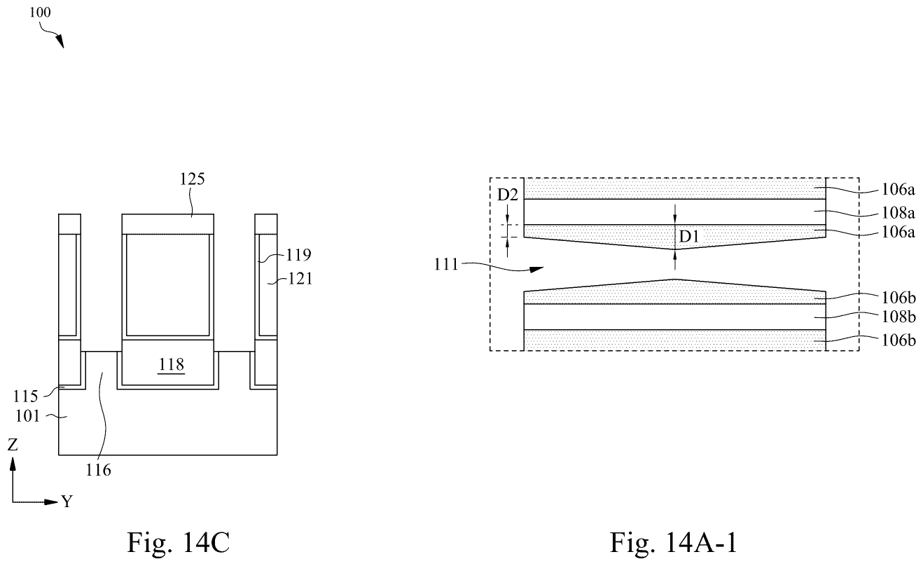

In FIGS. 14A-14C, the sacrificial layer 109 is selectively removed, resulting in a cavity 111 between the first semiconductor layer 106a in the first FET and the first semiconductor layer 106b in the second FET. The removal of the sacrificial layer 109 may be performed using an etchant 113 that selectively removes the sacrificial layer 109 without substantially affecting the first and second semiconductor layers 106, 108. In some embodiments, the sacrificial layer 109 is removed by hydrogen fluoride (HF) (vapor or liquid). Other suitable fluoride, such as hydroboron tetrafluoride (HBF₄) or ammonium fluoride (NH₄F), may also be used. The removal process may cause some of the atoms (e.g., alkaline elements Sr or Ti) that were previously in the sacrificial layer 109 to diffuse into the neighboring layers (e.g., first semiconductor layers 106a, 106b).

In some embodiments, a portion of the first semiconductor layer 106 and a portion of the second semiconductor layer 108 are slightly removed. In some examples, the first semiconductor layer 106 may be removed by a first amount and the second semiconductor layer 108 may be removed by a second amount that is greater than the first amount. In such cases, the sidewall surface of each second semiconductor layer 108 (e.g., 108a, 108b) of the stack of semiconductor layers 104 may be recessed horizontally along the X direction by a first distance with respect to the sidewall surface of the gate spacer 138, and the sidewall surface of each first semiconductor layer 106 (e.g., 106a, 106b) of the stack of semiconductor layers 104 may be recessed horizontally along the X direction by a second distance with respect to the sidewall surface of the gate spacer 138, wherein the first distance is greater than the second distance.

In some embodiments, the first semiconductor layers 106a in the first FET may be removed by a first amount and the first semiconductor layers 106b in the second FET may be removed by a second amount that is less than the first amount due to high aspect ratio of the trenches. Likewise, the second semiconductor layers 108a in the first FET may be removed by a third amount and the second semiconductor layers 108b in the second FET may be removed by a fourth amount that is less than the third amount.

FIG. 14A-1 illustrates an enlarged view of a portion 137 of the semiconductor device structure 100 showing the profile of the cavity 111, in accordance with some embodiments. In one embodiment, the sacrificial layer 109 is removed such that edge portions of the first semiconductor layers 106a, 106b may suffer more loss than at the center portion, leading to the cavity 111 wider at the edge and narrower at the center. Stated differently, the first semiconductor layers 106a, 106b may have a slope where the thickness of the first semiconductor layers 106a, 106b decreases from center to edge. For example, each first semiconductor layer 106a, 106b may have a first thickness D1 measuring at the center and a second thickness D2 measuring at the edge, wherein the first thickness D1 is greater than the second thickness D2.

After the sacrificial layer 109 is removed, a pre-clean process may be performed to remove any debris or residues generated as a result of the removal of the sacrificial layer 109. The pre-clean process may use an etchant that does not substantially affecting the first and second semiconductor layers 106, 108, and the sacrificial gate structure 130. In some embodiments, the pre-clean may use a diluted HF solution. Other suitable wet etch process may also be used. For example, the pre-clean process may be any suitable wet cleaning process such as an APM process, which includes at least water (H₂O), ammonium hydroxide (NH₄OH), and hydrogen peroxide (H₂O₂), a HPM process, which includes at least H₂O, H₂O₂, and hydrogen chloride (HCl), a SPM process (also known as piranha clean), which includes at least H₂O₂ and sulfuric acid (H₂SO₄), or any combination thereof.

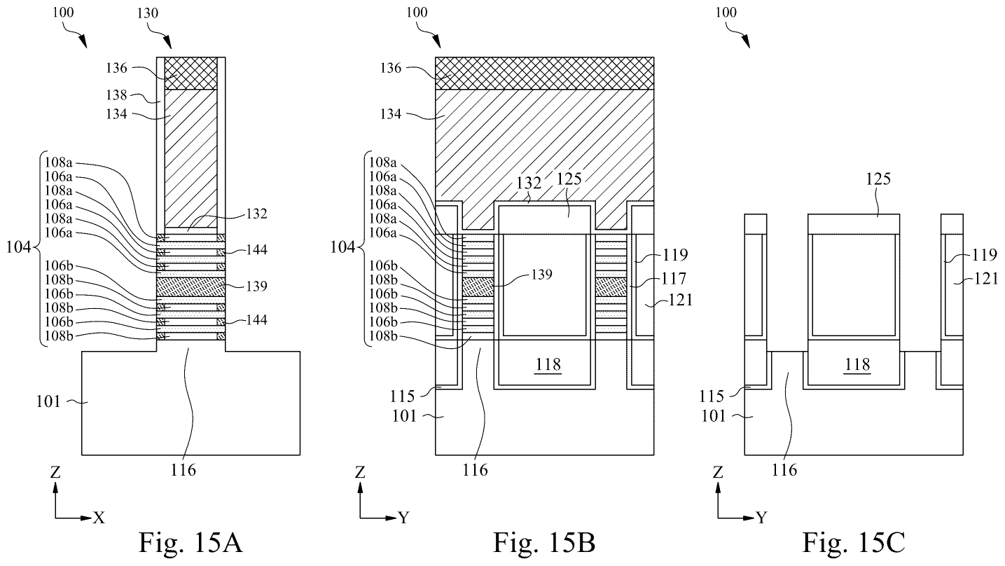

In FIGS. 15A-15C, edge portions of each second semiconductor layer 108 (e.g., 108a, 108b) of the stack of semiconductor layers 104 are removed horizontally along the X direction. The removal of the edge portions of the second semiconductor layers 108 forms cavities. In some embodiments, the portions of the second semiconductor layers 108 are removed by a selective wet etching process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers (or so-called inner spacer) 144. The dielectric layer is also deposited in the cavity 111 to form an isolation layer 139. The isolation layer 139 and dielectric spacers 144 may be made of a dielectric material, such as SiON, SiCN, SiOC, SiOCN, SiN, or the like. The isolation layer 139 and dielectric spacers 144 may be formed by first forming a conformal dielectric layer using a conformal deposition process, such as ALD, followed by an anisotropic etching to remove portions of the conformal dielectric layer other than the isolation layer 139 and the dielectric spacers 144. The isolation layer 139 and the dielectric spacers 144 are protected by the first semiconductor layers 106 during the anisotropic etching process. The remaining second semiconductor layers 108 (e.g., 108a, 108b) are capped between the dielectric spacers 144 along the X direction.

In FIGS. 16A-16C, epitaxial S/D features 146 are formed on the well portion 116 of the fin structures 112. The epitaxial S/D features 146 may include or be made of one or more layers of Si, SiP, SiC and SiCP for n-channel FETs or Si, SiGe, Ge for p-channel FETs. For p-channel FETs, p-type dopants, such as boron (B), may also be included in the epitaxial S/D features 146. In some embodiments, the epitaxial S/D feature 146 uses one or more layers of Si, SiGe, and Ge for a p-channel FET. The epitaxial S/D features 146 may be formed by an epitaxial growth method using CVD, ALD or MBE. The epitaxial S/D features 146 may grow both vertically and horizontally to form facets, which may correspond to crystalline planes of the material used for the substrate 101. The epitaxial S/D features 146 are in contact with the first semiconductor layers 106a, 106b, the isolation layer 139, and dielectric spacers 144, as shown in FIG. 15A. The epitaxial S/D epitaxial features 146 may be the S/D regions. In this disclosure, a source region and a drain region are interchangeably used, and the structures thereof are substantially the same.

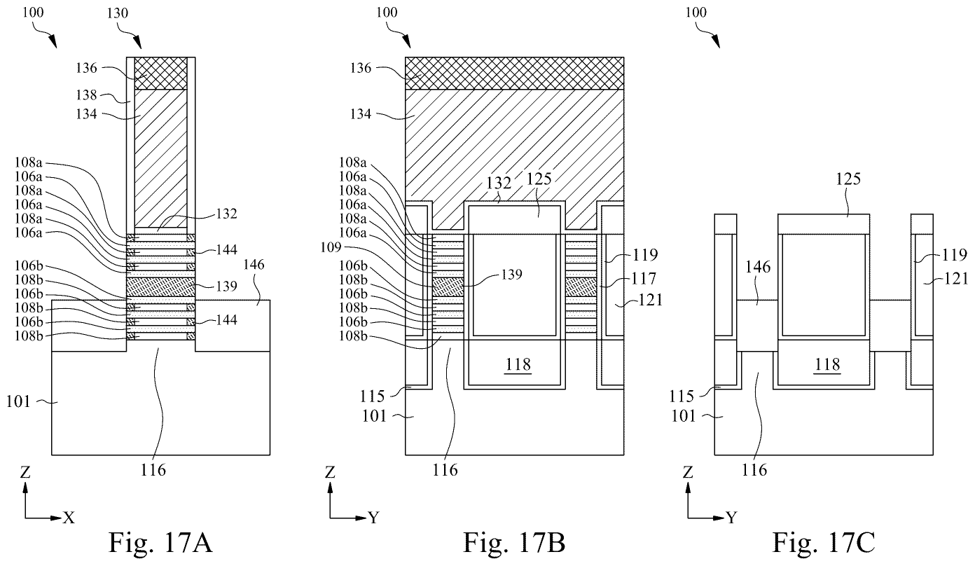

In FIGS. 17A-17C, the epitaxial S/D features 146 are recessed by removing a portion of each epitaxial S/D feature 146. The recess of the epitaxial S/D features 146 may be performed by any suitable process, such as dry etch or wet etch that selectively removes a portion of each epitaxial S/D feature 146 but not the gate spacer 138, the dielectric material 125, and the liner 119. After the removal process, the epitaxial S/D features 146 remain in contact with the first semiconductor layers 106b, the and the dielectric spacers 144, as shown in FIG. 17A. In some embodiments, the epitaxial S/D features 146 may be at or near an interface of the isolation layer 139 and the topmost first semiconductor layer 106b of the second FET. In some embodiments, the etch process may be performed so that a lower portion of the isolation layer 139 is in contact with the epitaxial S/D feature 146. In any case, the semiconductor device structure 100 includes a nanosheet p-channel FET having a source epitaxial feature/terminal 146 and a drain epitaxial feature/terminal 146 both in contact with one or more first semiconductor layers 106b, or one or more channels.

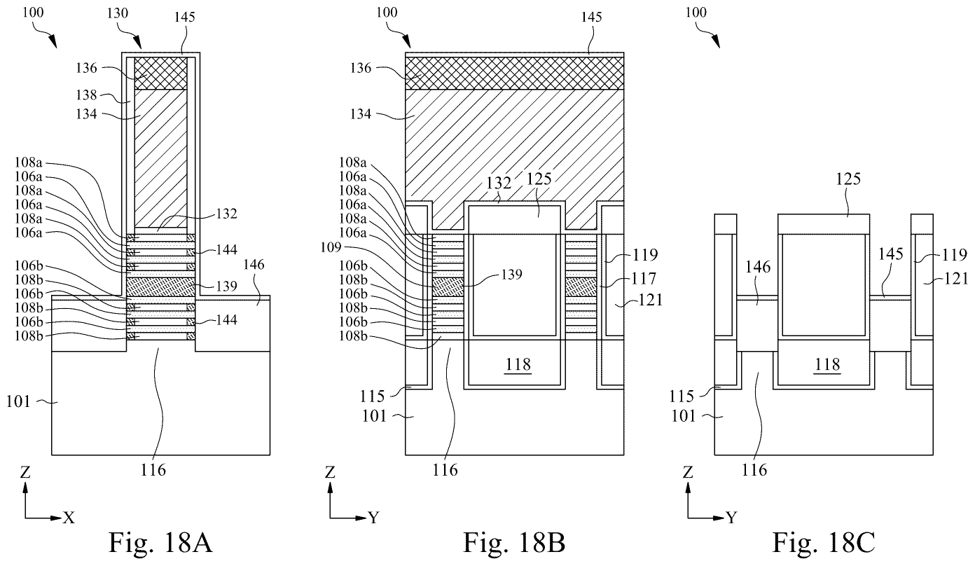

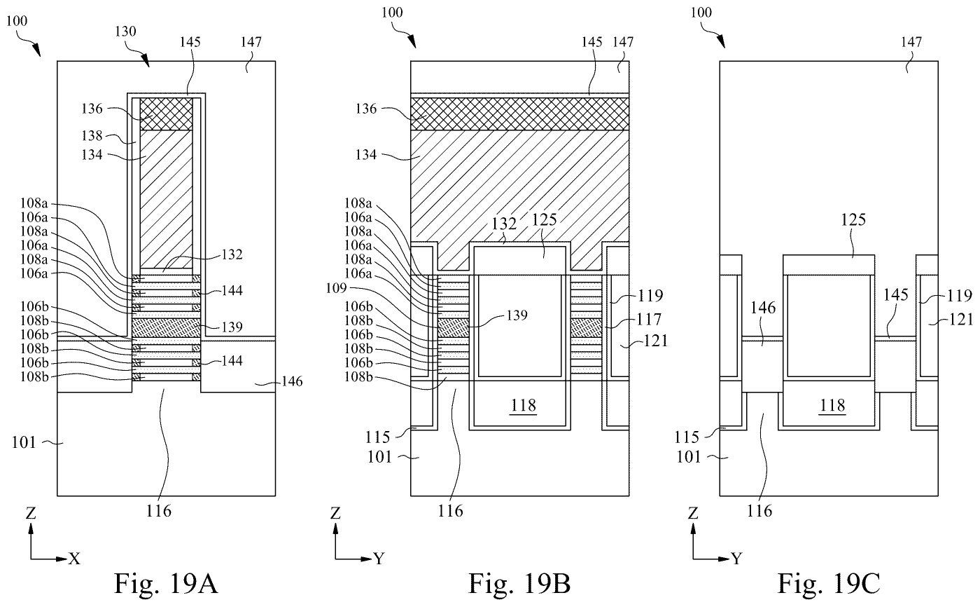

In FIGS. 18A-18C, a liner 145 is formed on the exposed surfaces of the semiconductor device structure 100. In some embodiments, the liner 145 is formed on at least the epitaxial S/D features 146, the sidewalls of the sacrificial gate structures 130, the sidewalls of the exposed isolation layer 139, the dielectric spacers 144, and second semiconductor layers 108. The liner 145 may include a semiconductor material, such as Si. In some embodiments, the liner 145 includes the same material as the first semiconductor layers 106. The liner 145 may be a conformal layer and may be formed by a conformal process, such as an ALD process. The liner 145 protects the mask layer 136, the gate spacers 138, the second semiconductor layers 108, the isolation layer 139, and the dielectric spacers 144 during subsequent recess of a dielectric material 147 (FIG. 19A).

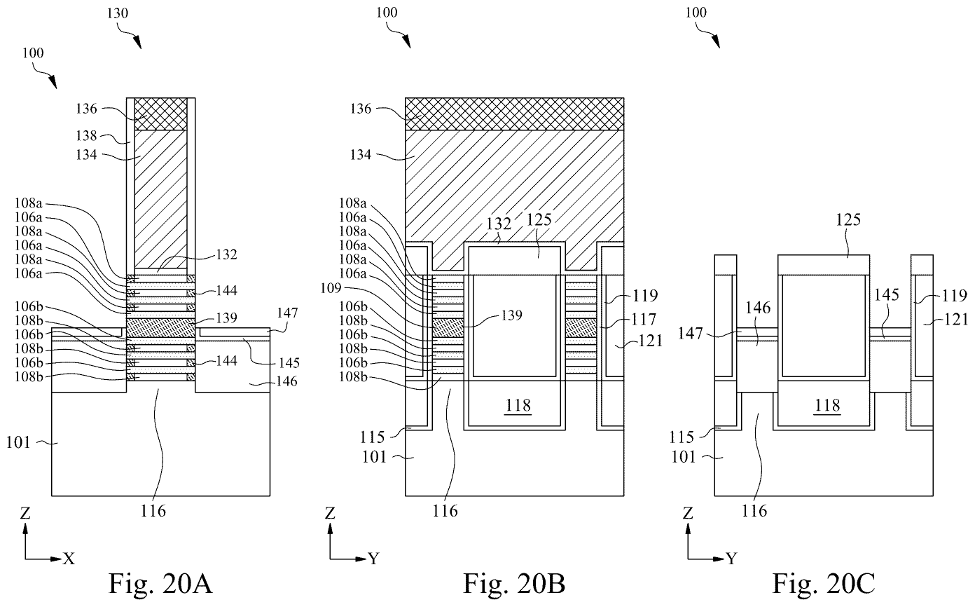

In FIGS. 19A-19C, a dielectric material 147 is formed over the epitaxial S/D features 146. The dielectric material 147 may include the same material as the insulating material 118 and may be formed by the same method as the insulating material 118. In some embodiments, the dielectric material 147 includes an oxide that is formed by FCVD. The dielectric material 147 may be recessed to a level below the level of the first semiconductor layers 106a, as shown in FIG. 20A. The recess of the dielectric material 147 may be performed by any suitable process, such as dry etch or wet etch that selectively removes a portion of the dielectric material 147 but not the gate spacer 138, the first semiconductor layer 106a, and the dielectric spacers 144.

In FIGS. 19A-19C, a dielectric material 147 is formed on the liner 145 and over the epitaxial S/D features 146. The dielectric material 147 may include the same material as the insulating material 118 and may be formed by the same method as the insulating material 118. In some embodiments, the dielectric material 147 includes an oxide that is formed by FCVD.

In FIGS. 20A-20C, the dielectric material 147 is recessed to a level below the level of the bottommost first semiconductor layer 106a of the first FET. The recess of the dielectric material 147 may be performed by any suitable process, such as dry etch or wet etch that selectively removes a portion of the dielectric material 147 but not the liner 145. Next, the exposed liner 145 is removed, as shown in FIG. 20A. The removal of the exposed liner 145 may be performed by any suitable process, such as dry etch or wet etch that selectively removes portions of the liner 145 but not the dielectric material 125, the gate spacer 138, the mask layer 136, and the dielectric material 147. Because the thickness of the liner 145 is less than about 1.5 nm, the etch process removing portions of the liner 145 may be performed in a short period of time, so the exposed second semiconductor layers 108b are not substantially affected by the etch process.

The remaining liner 145 may be level with the recessed dielectric material 147. The liner 145 may remain in contact with the topmost second semiconductor layers 108b, the isolation layer 139, and the epitaxial S/D feature 146. Thus, the remaining liner 145 may surround five surfaces of the recessed dielectric material 147.

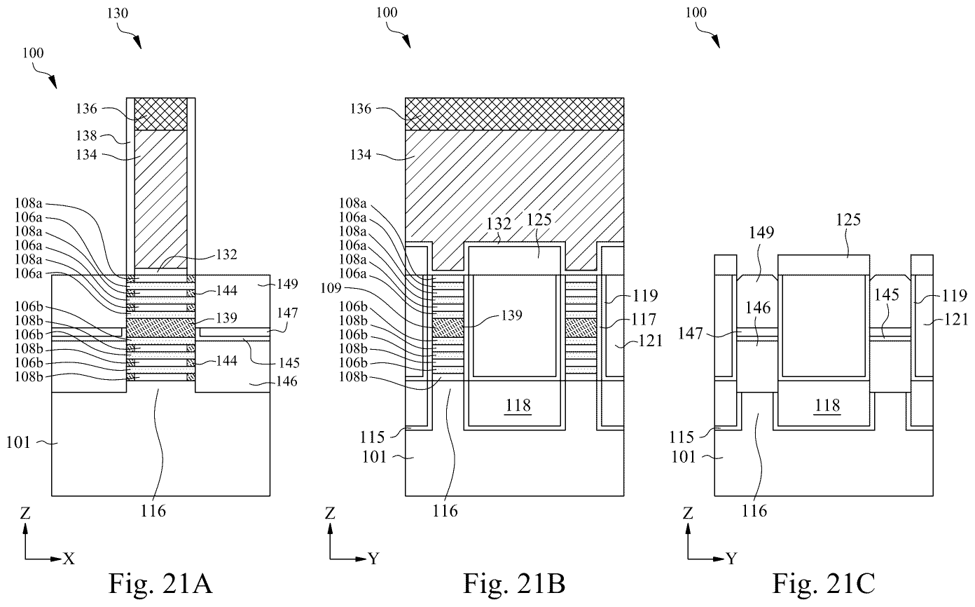

In FIGS. 21A-21C, epitaxial S/D features 149 are formed on the dielectric material 147. The epitaxial S/D feature 149 may include one or more layers of Si, SiP, SiC and SiCP for an n-channel FET or Si, SiGe, Ge for a p-channel FET. In some embodiments, the epitaxial S/D feature 149 uses one or more layers of Si, SiP, SiC and SiCP for a n-channel FET. The epitaxial S/D features 149 may be formed from the first semiconductor layers 106a (FIG. 17A). The epitaxial S/D features 149 may grow both vertically and horizontally to form facets, which may correspond to crystalline planes of the material used for the first semiconductor layers 106a. The epitaxial S/D features 149 may be formed by an epitaxial growth method using CVD, ALD or MBE. Likewise, the epitaxial S/D features 149 may be the S/D regions.

As shown in FIGS. 21A and 21C, the source regions of the n-channel FETs and p-channel FETs may be vertically stacked and aligned, the drain regions of the n-channel FETs and the p-channel FETs may be vertically stacked and aligned, and the source of the n-channel FET and the source of the p-channel FET may be separated by the liner 145 and the dielectric material 147. Vertical stacking of the n-channel FETs and p-channel FETs can increase the density of the FETs while reducing the cell active area footprint for the semiconductor devices, such as SRAMs.

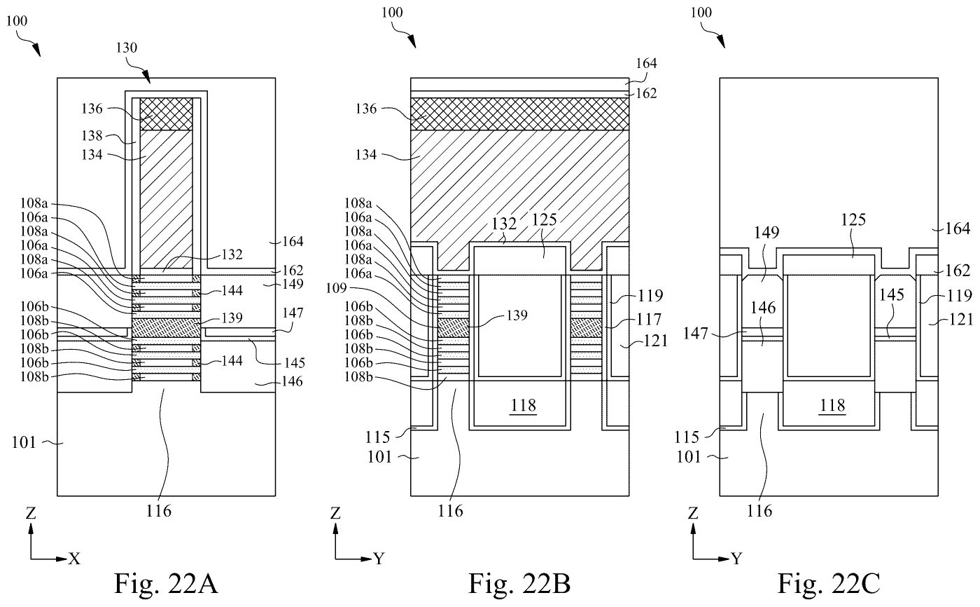

In FIGS. 22A-22C, a contact etch stop layer (CESL) 162 is conformally formed on the exposed surfaces of the semiconductor device structure 100. The CESL 162 covers the epitaxial S/D features 146, the gate spacers 138, the dielectric material 125, and the exposed surface of the stack of semiconductor layers 104. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials comprising Si, O, C, and/or H. The ILD layer 164 may be deposited by a PECVD process or other suitable deposition technique. In some embodiments, after formation of the ILD layer 164, the semiconductor device structure 100 may be subject to a thermal process to anneal the ILD layer 164.

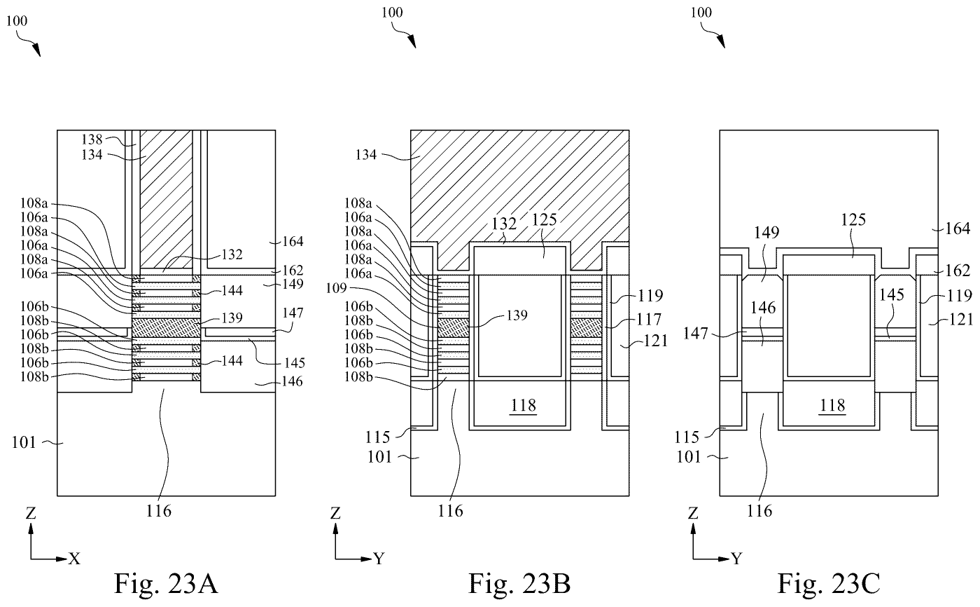

In FIGS. 23A-23C, after the ILD layer 164 is formed, a planarization operation, such as CMP, is performed on the semiconductor device structure 100 to remove portions of the ILD layer 164, the CESL 162 and the mask layer 136 until the sacrificial gate electrode layer 134 is exposed.

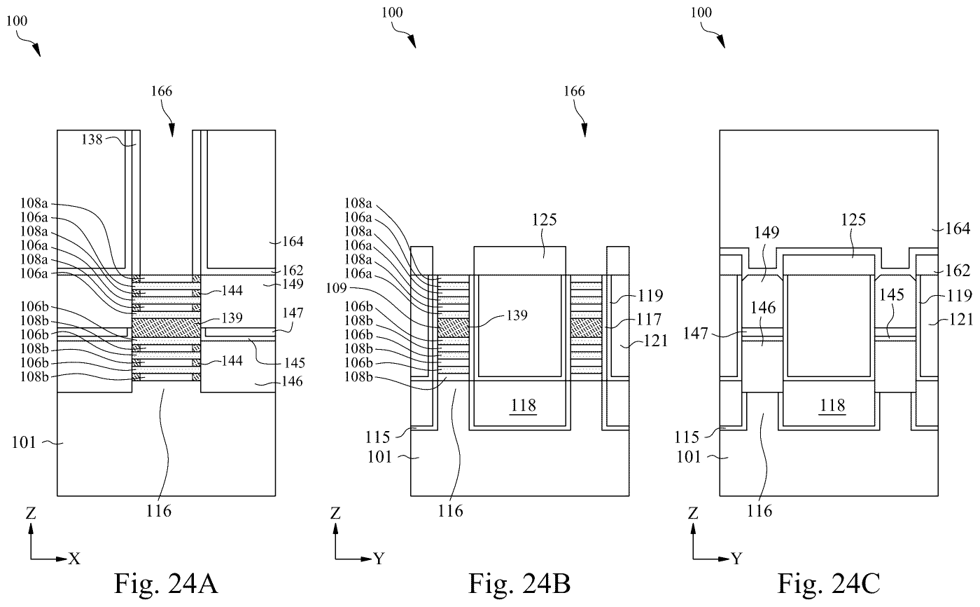

In FIGS. 24A-24C, the sacrificial gate structure 130 is removed. The removal of the sacrificial gate structure 130 forms a trench 166 in the regions where the sacrificial gate electrode layer 134 and the sacrificial gate dielectric layer 132 were removed. The trench 166 exposes portions of the cladding layer 117 and the top of the second semiconductor layer 108a. The ILD layer 164 protects the epitaxial S/D features 146 during the removal of the sacrificial gate structure 130. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the dielectric material 125, and the CESL 162. In some embodiments, the gate spacers 138 may be recessed by the etchant used to remove the sacrificial gate electrode layer 134 and/or the sacrificial gate dielectric layer 132.

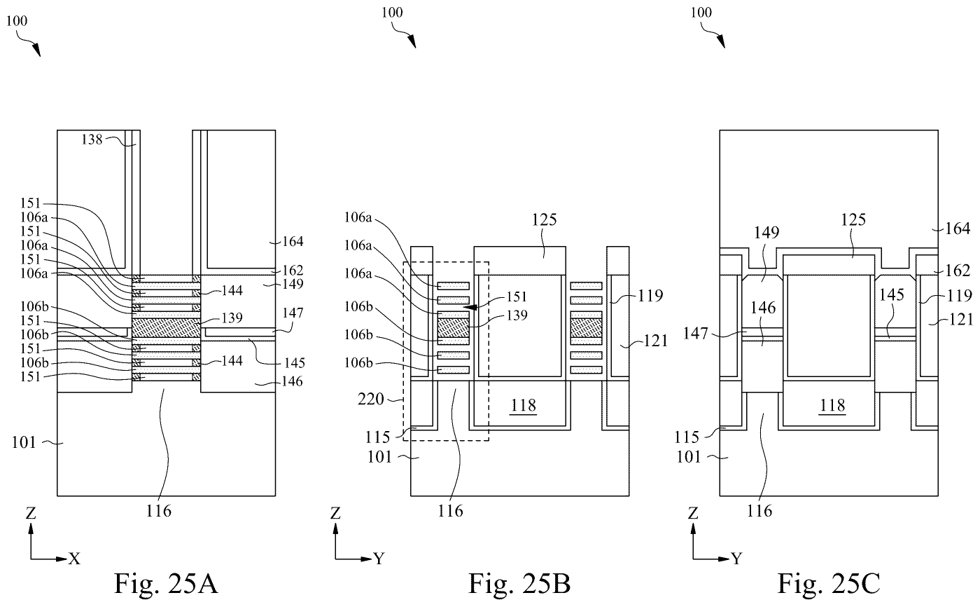

In FIGS. 25A-25C, the cladding layers 117 and the second semiconductor layers 108 (e.g., 108a, 108b) are removed. The removal of the cladding layers 117 and the second semiconductor layers 108 exposes the isolation layer 139, the dielectric spacers 144, and the first semiconductor layers 106 (e.g., 106a, 106b). The removal process may be any suitable etch processes, such as dry etch, wet etch, or a combination thereof. The etch process may be a selective etch process that removes the cladding layers 117 and the second semiconductor layers 108 but not the gate spacers 138, the CESL 162, the dielectric material 125, and the first semiconductor layers 106. As a result, openings 151 are formed around the first semiconductor layers 106, as shown in FIGS. 25A and 25B. That is, the portion of the first semiconductor layers 106 not covered by the dielectric spacers 144 is exposed to the openings 151.

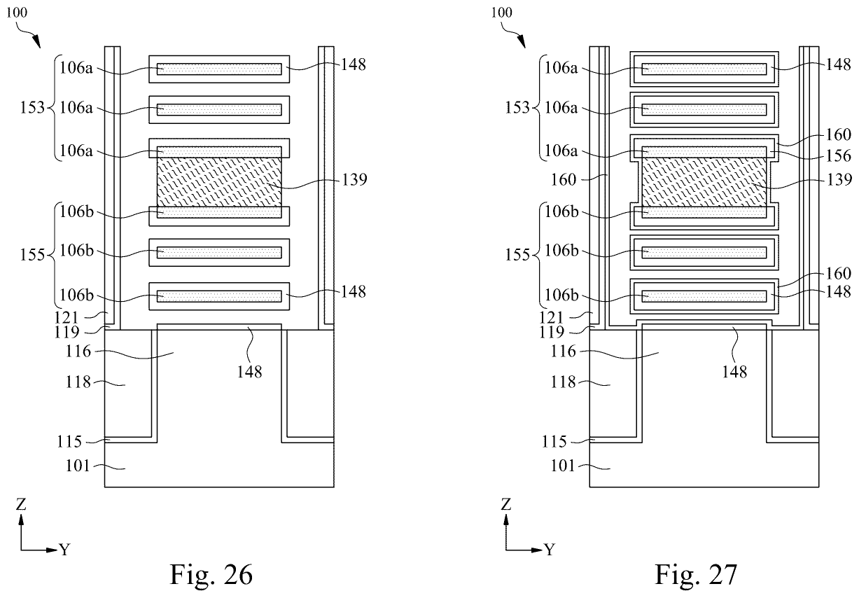

FIGS. 26-30 are enlarged views of a region 220 of FIG. 25B showing various stages of manufacturing the semiconductor device structure 100 in accordance with some embodiments. For the sake of clarity, the dielectric material 125 is omitted in FIGS. 26-30. In the embodiment shown in FIG. 26, each first semiconductor layer 106b may be a nanosheet channel of a first nanosheet transistor 155, such as a p-channel FET, and each first semiconductor layer 106a may be a nanosheet channel of a second nanoshect transistor 153, such as a n-channel FET. The second nanosheet transistors (e.g., 106a) are disposed over and aligned with the first nanosheet transistors (e.g., 106b) along the Z-direction. Depending on the application, nanosheet transistors having higher thermal budget (e.g., p-channel FETs) may be arranged below nanosheet transistors having lower thermal budget (e.g., n-channel FETs).

In FIG. 26, the semiconductor device structure 100 may be subjected to a pre-clean process to remove residues or unwanted films from exposed surfaces of the first semiconductor layers 106b of the first nanosheet transistor 155 and the first semiconductor layer 106a of the second nanosheet transistor 153. The pre-clean process may be any suitable wet cleaning process such as those discussed above after the sacrificial layer 109 is removed.

Next, an interfacial layer (IL) 148 is formed to surround the exposed surfaces of the first semiconductor layers 106a, 106b, as shown in FIG. 26. In some embodiments, the IL 148 may also form on the well portion 116 of the substrate 101. The IL 148 may include or be made of an oxygen-containing material or a silicon-containing material, such as silicon oxide, silicon oxynitride, oxynitride, hafnium silicate, etc. The IL 148 may be formed by CVD, ALD or any suitable conformal deposition technique.

In FIG. 27, a high-K (HK) dielectric layer 160 is formed on the exposed surfaces of the semiconductor device structure 100. In some embodiments, the HK dielectric layer 160 is formed to wrap around the exposed surfaces of the IL 148, the isolation layer 139, the liner 119, the insulating material 118, and the liner 115. The HK dielectric layer 160 may include or made of hafnium oxide (HfO₂), hafnium silicate (HfSiO), hafnium silicon oxynitride (HfSiON), hafnium aluminum oxide (HfAIO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AIO), aluminum silicon oxide (AlSiO), zirconium oxide (ZrO), titanium oxide (TiO), tantalum oxide (Ta₂O₅), yttrium oxide (Y₂O₃), silicon oxynitride (SiON), or other suitable high-k materials. The HK dielectric layer 160 may be a conformal layer formed by a conformal process, such as an ALD process or a CVD process.

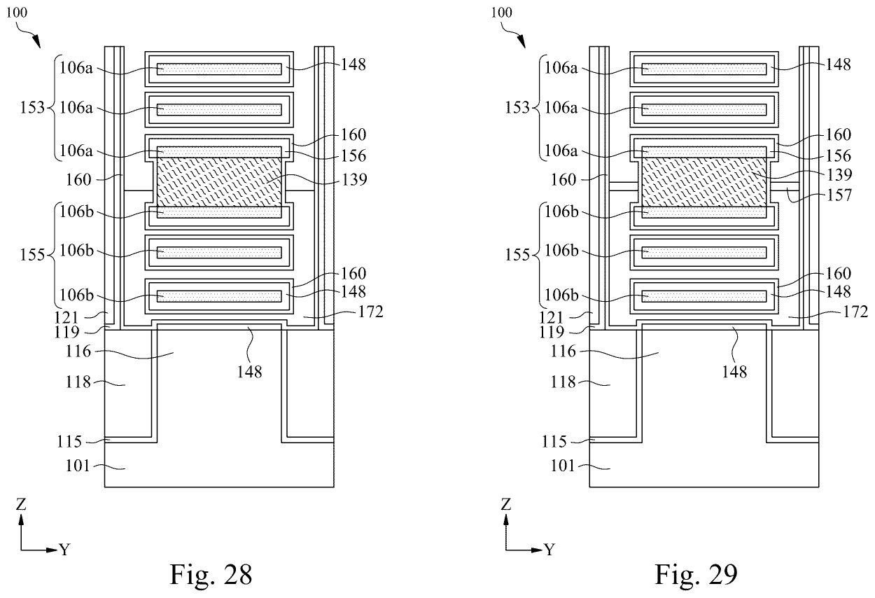

In FIG. 28, a first gate electrode layer 172 is formed in each opening 151 (FIG. 25B) and on the HK dielectric layer 160. The first gate electrode layer 172 is formed on the HK dielectric layer 160 to surround a portion of each first semiconductor layer 106b, 106a, respectively. The first gate electrode layer 172 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAIN, TaN, TaCN, TaC, TaSiN, metal alloys, other suitable materials, and/or combinations thereof. The first gate electrode layers 172 may be formed by PVD, CVD, ALD, electro-plating, or other suitable method. In some embodiments, the first gate electrode layer 172 includes a p-type gate electrode layer such as TIN, TaN, TiTaN, TiAIN, WCN, W, Ni, Co, or other suitable material, and the first gate electrode layer 172 is a gate electrode layer of a PFET. The first gate electrode layer 172 may be formed by first forming a gate electrode layer filling the opening 151, followed by an etch back process to recess the gate electrode layer to a level at or near the center region of the isolation layer 139. In some embodiments, the first gate electrode layer 172 is recessed such that a top surface of the first gate electrode layer 172 is at a level slightly above an interface defined by a bottom surface of the isolation layer 139 and a top surface of the topmost first semiconductor layer 106b, as shown in FIG. 28. The top surface of the first gate electrode layer 172 generally defines the boundary between the first nanosheet transistor 155 and the second nanosheet transistor 153.

In FIG. 29, an isolation material layer 157 is formed in each opening 151 and on the first gate electrode layer 172. The isolation material layer 157 may include one or more layers of dielectric material, such as a metal oxide, for example a refractory metal oxide. The isolation material layer 157 may be formed by PVD, CVD, PECVD, ALD, electro-plating, or other suitable method. The isolation material layer 157 may be formed by first forming a dielectric layer filling the opening 151, followed by an etch back process to recess the dielectric layer to a level below an interface defined by the bottom surface of the bottommost first semiconductor layer 106a of the second nanosheet transistor 153 and the top surface of the isolation layer 139.

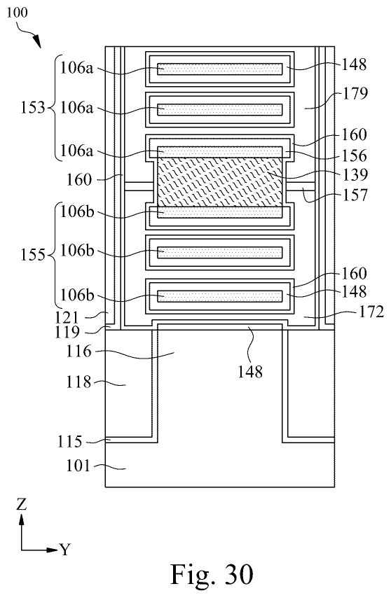

In FIG. 30, a second gate electrode layer 179 is formed on the isolation material layer 157 and filled in the opening 151 revealed as the result of the recess of the isolation material layer 157. The second gate electrode layer 179 includes one or more layers of conductive material, such as polysilicon, aluminum, copper, titanium, tantalum, tungsten, cobalt, molybdenum, tantalum nitride, nickel silicide, cobalt silicide, TIN, WN, WCN, TiAl, TiTaN, TiAIN, TaN, TaCN, TaC, TaSiN, metal alloys, other suitable materials, and/or combinations thereof. The first gate electrode layer 172 and the second gate electrode layer 179 may include the same or different materials. The second gate electrode layers 179 may be formed by PVD, CVD, ALD, electro-plating, or other suitable method. In some embodiments, the second gate electrode layer 179 includes an n-type gate electrode layer such as TiAIC, TaAIC, TiSiAIC, TiC, TaSiAIC, or other suitable material. Therefore, the second gate electrode layer 179 serves as a gate electrode layer for an n-channel FET, and the first gate electrode layer 172 serves as a gate electrode layer for a p-channel FET.

While the first nanosheet transistor 155 (e.g., a p-channel FET) and the second nanosheet transistor 153 (e.g., a n-channel FET) are shown to have the same number of channel layers (e.g., first semiconductor layers 106a, 106b), it is understood that uneven number of channel layers are contemplated. For example, the first nanosheet transistor 155 may have a first number of channel layers and the second nanosheet transistor 153 may have a second number of channel layers that are less or greater than the first number of channel layers.

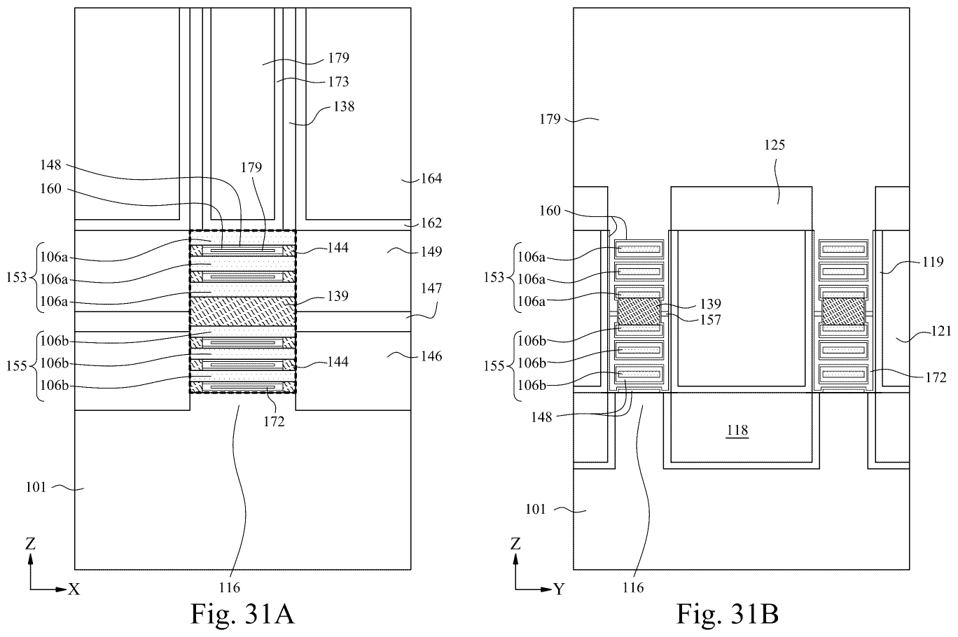

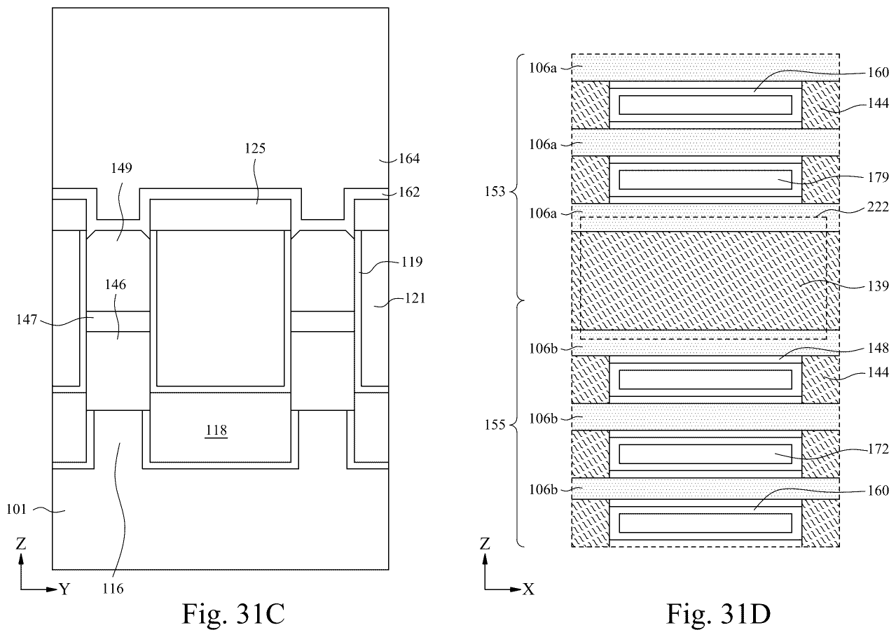

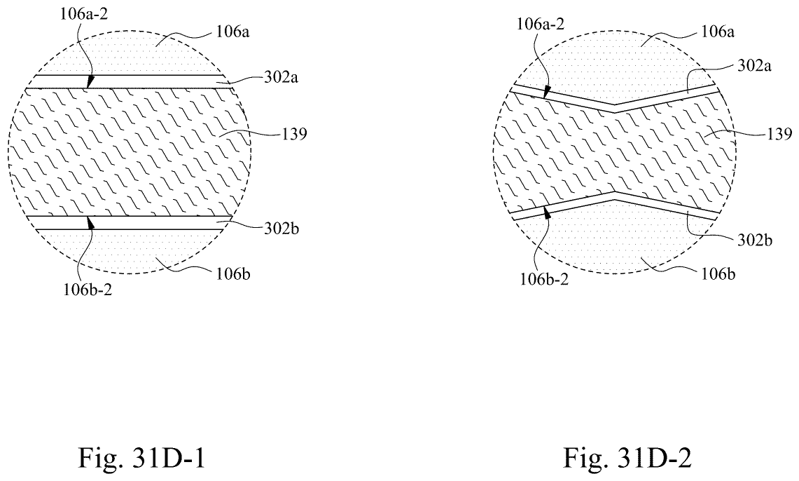

FIGS. 31A, 31B, and 31C illustrate cross-sectional side views of the semiconductor device structure 100 after the first and second gate electrode layers 172 and 179 are formed. FIG. 31D is an enlarged view of a portion of the semiconductor device structure 100 showing the first and second nanosheet transistors 155, 153. FIG. 31D-1 is an enlarged view of a region 222 of the semiconductor device structure 100 shown in FIG. 31D. As discussed above with respect to FIG. 13D, the atoms in the first semiconductor layers 106a, 106b may have a gradual gradient distribution. For example, the first semiconductor layer 106a may have a first element concentration at and/or near an interface 106a-2 of the isolation layer 139 and the first semiconductor layer 106a, and a second element concentration at and/or near the center region of the first semiconductor layer 106a, wherein the first element concentration is greater than the second element concentration. Likewise, the first semiconductor layer 106b may have a first element concentration at and/or near an interface 106b-2 of the isolation layer 139 and the first semiconductor layer 106b, and a second element concentration at and/or near the center region of the first semiconductor layer 106b, wherein the profile of the atom distribution is gradually decreasing from the first element concentration to the second element concentration. In such cases, atoms (e.g., alkaline elements Sr or Ti) previously diffused from the sacrificial layer 109 may form a material layer 302a, 302b containing Sr or Ti at and/or near the interface 106a-2, 106b-2, respectively.

FIG. 31D-2 is an enlarged view of a region 222 of the semiconductor device structure 100 shown in FIG. 31D, in accordance with the embodiment shown in FIG. 14A-1. In such cases, the material layer 302a, 302b and the isolation layer 139 are deposited to follow the profile of the first semiconductor layers 106a, 106b, which have a thickness decreasing from center to edge. As a result, the isolation layer 139 is formed with a greater thickness at the edge and a smaller thickness at the center.

In some embodiments, atoms (e.g., alkaline elements Sr or Ti) in the material layers 302a, 302b may back diffuse to the isolation layer 139, resulting in the isolation layer 139 with an element concentration of Sr or Ti that is different than that of the material layers 302a, 302b. For example, the first semiconductor layers 106a, 106b may contain a first element concentration, the material layers 302a, 302b may have a second element concentration greater than the first element concentration, and the isolation layer 139 may have a third element concentration less than the second element concentration.

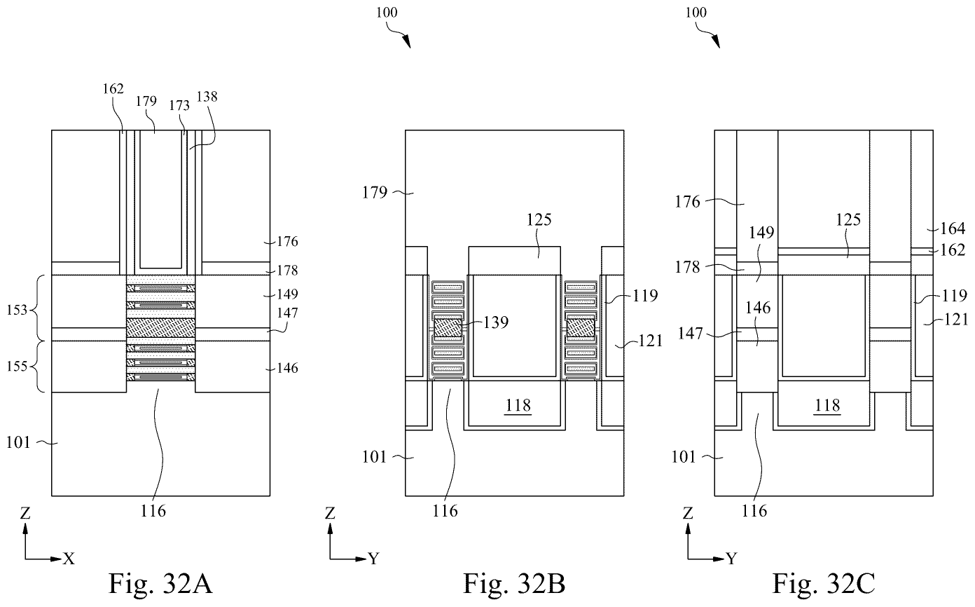

In FIGS. 32A-32C, source/drain (S/D) contacts 176 are formed in the ILD layer 164. Prior to forming the S/D contacts 176, contact openings are formed in the ILD layer 164 to expose the epitaxial S/D feature 149. Suitable photolithographic and etching techniques are used to form the contact openings through various layers, including the ILD layer 164 and the CESL 162 to expose the epitaxial S/D features 149.

After the formation of the contact openings, a silicide layer 178 is formed on the epitaxial S/D features 149. The silicide layer 178 conductively couples the epitaxial S/D features 149 to the subsequently formed S/D contacts 176. The silicide layer 178 may be formed by depositing a metal source layer over the epitaxial S/D features 149 and performing a rapid thermal annealing process. During the rapid anneal process, the portion of the metal source layer over the epitaxial S/D features 149 reacts with silicon in the epitaxial S/D features 149 to form the silicide layer 178. Unreacted portion of the metal source layer is then removed. The material of the silicide layer 178 is chosen based on the conductivity type of the second nanosheet transistor 153. For n-channel FETs, the silicide layer 178 may be made of a material including one or more of TiSi, CrSi, TaSi, MoSi, ZrSi, HfSi, ScSi, YSi, HoSi, TbSI, GdSi, LuSi, DySi, ErSi, YbSi, or combinations thereof. For p-channel FETs, the silicide layer 178 may be made of a material including one or more of NiSi, CoSi, MnSi, WSi, FeSi, RhSi, PdSi, RuSi, PtSi, IrSi, OsSi, or combinations thereof. In some embodiments, the silicide layer 178 is made of a metal or metal alloy silicide, and the metal includes a noble metal, a refractory metal, a rare earth metal, alloys thereof, or combinations thereof.

Next, a conductive material is formed in the contact openings and form the S/D contacts 176. The conductive material may be made of a material including one or more of Ru, Mo, Co, Ni. W, Ti, Ta, Cu, Al, TiN and TaN. While not shown, a barrier layer (e.g., TiN, TaN, or the like) may be formed on sidewalls of the contact openings prior to forming the S/D contacts 176. Then, a planarization process, such as CMP, is performed to remove excess deposition of the contact material and expose the top surface of the second gate electrode layer 179.

It is understood that the semiconductor device structure 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 by flipping over the semiconductor device structure 100, removing the substrate 101, and selectively connecting source or drain feature/terminal of the epitaxial S/D features 146 or 149 to a backside power rail (e.g., positive voltage VDD or negative voltage VSS) through the backside contacts. Depending on the application, the source or drain feature/terminal of the epitaxial S/D features 146 or 149 and the first and second gate electrode layers 172, 179 may be connected to a frontside power source.

Embodiments of the present disclosure provide a semiconductor device structure including CFETs each having a first nanosheet transistor and a second nanosheet transistor disposed over the first nanosheet transistor. The first nanosheet transistor is separated from the second nanosheet transistor by an isolation layer, and each channel layer disposed immediately adjacent to the isolation layer has alkaline atoms (e.g., Sr or Ti) diffused from a sacrificial layer that was previously formed and then removed prior to formation of source/drain features. As opposed to old approach using SiGe with high Ge at. % (e.g., 50 at. %) as the sacrificial layer, the inventive sacrificial layer is made of semiconductor metal oxides, such as alkaline earth titanate. Alkaline earth titanate such as SrTiO₃ is a wide bandgap semiconductor having a great etching selectivity with respect to silicon, and can grow on silicon with minimum or no lattice mismatch between the sacrificial layer and the neighboring channel layers. As a result, dislocation issues that may occur as a result of lattice mismatch between the sacrificial layer and the neighboring channel layers are mitigated.

A method for forming a semiconductor device structure is provided. The method includes forming a sacrificial layer between a first stack of layers and a second stack of layers disposed over the first stack of layers, wherein the first stack of layers comprises a plurality of first semiconductor layers and a plurality of second semiconductor layers alternatingly stacked, and the second stack of layers comprises a plurality of third semiconductor layers and a plurality of fourth semiconductor layers alternatingly stacked, and wherein the sacrificial layer comprises a semiconductor metal oxide. The method also includes forming a sacrificial gate structure over a portion of the second stack of layers, removing portions of the first and second stack of layers not covered by the sacrificial gate structure, removing the sacrificial layer to form a cavity, filling the cavity with a dielectric material to form an isolation layer, and forming a first source/drain feature and a second source/drain feature on opposing sides of the sacrificial gate structure, wherein the first source/drain feature is disposed below the second source/drain feature, and the first source/drain feature and the second source/drain feature are in contact with the isolation layer, the first semiconductor layers, and the third semiconductor layers.

Another embodiment is a method for forming a semiconductor device structure. The method includes forming a plurality of fin structures from a substrate, each fin structure comprising a plurality of first semiconductor layers and a plurality of second semiconductor layers alternatingly stacked, forming a sacrificial layer between two immediately adjacent first semiconductor layers, wherein the sacrificial layer comprises a semiconductor metal oxide. The method also includes diffusing metal elements from the sacrificial layer into the first semiconductor layers immediately disposed adjacent to the sacrificial layer, and replacing the sacrificial layer with a dielectric material to form an isolation layer.

A further embodiment is a semiconductor device structure. The structure includes forming a first transistor comprising a plurality of first semiconductor layers vertically stacked, each first semiconductor layer being surrounded by a first gate electrode layer, a second transistor disposed over the first transistor, the second transistor comprising a plurality of second semiconductor layers vertically stacked, and each second semiconductor layer being surrounded by a second gate electrode layer that is different than the first gate electrode layer, an isolation layer disposed between a topmost first semiconductor layer of the first transistor and a bottommost second semiconductor layer of the second transistor, a first source/drain feature in contact with the first semiconductor layers and a portion of the isolation layer, and a second source/drain feature disposed over the first source/drain feature and in contact with the second semiconductor layers and a portion of the isolation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first transistor comprising a plurality of first semiconductor layers vertically stacked, each first semiconductor layer being surrounded by a first gate electrode layer; a second transistor disposed over the first transistor, the second transistor comprising a plurality of second semiconductor layers vertically stacked, each second semiconductor layer being surrounded by a second gate electrode layer different from the first gate electrode layer;
an isolation layer disposed between a topmost first semiconductor layer of the first transistor and a bottommost second semiconductor layer of the second transistor, the isolation layer comprising a dielectric material;
a first source/drain feature in contact with the first semiconductor layers and a portion of the isolation layer; and
a second source/drain feature disposed over the first source/drain feature and in contact with the second semiconductor layers and a portion of the isolation layer, wherein the topmost first semiconductor layer and the bottommost second semiconductor layer comprise alkaline elements diffused from a sacrificial layer comprising a semiconductor metal oxide.

2. The semiconductor device structure of claim 1, wherein the isolation layer comprises a material selected from the group consisting of SION, SiCN, SiOC, SiOCN, and SiN.

3. The semiconductor device structure of claim 1, wherein the alkaline elements comprise strontium (Sr) or titanium (Ti).

4. The semiconductor device structure of claim 1, wherein the topmost first semiconductor layer has a first element concentration of alkaline elements at an interface with the isolation layer and a second element concentration at a center region, the first element concentration being greater than the second element concentration.

5. The semiconductor device structure of claim 1, further comprising a dielectric material disposed between the first source/drain feature and the second source/drain feature, wherein a top surface of the dielectric material is at an elevation between a top surface and a bottom surface of the isolation layer.

6. The semiconductor device structure of claim 1, wherein the first gate electrode layer comprises a p-type gate electrode material and the second gate electrode layer comprises an n-type gate electrode material.

7. The semiconductor device structure of claim 1, further comprising:
dielectric spacers disposed adjacent to the first and second semiconductor layers, the dielectric spacers comprising the same material as the isolation layer.

8. The semiconductor device structure of claim 1, wherein the isolation layer has a thickness greater at an edge than at a center, corresponding to a profile of the sacrificial layer.

9. A method for forming a semiconductor device structure, comprising:
forming a sacrificial layer comprising a semiconductor metal oxide between a first stack of layers and a second stack of layers disposed over the first stack of layers, wherein the first stack of layers comprises a plurality of first semiconductor layers and a plurality of second semiconductor layers alternatingly stacked, and the second stack of layers comprises a plurality of third semiconductor layers and a plurality of fourth semiconductor layers alternatingly stacked;
forming a sacrificial gate structure over a portion of the second stack of layers;
removing portions of the first and second stack of layers not covered by the sacrificial gate structure; removing the sacrificial layer to form a cavity, wherein alkaline elements from the sacrificial layer diffuse into the first and third semiconductor layers adjacent to the sacrificial layer;
filling the cavity with a dielectric material to form an isolation layer; and
forming a first source/drain feature and a second source/drain feature on opposing sides of the sacrificial gate structure, wherein the first source/drain feature is disposed below the second source/drain feature, and the first and second source/drain features are in contact with the isolation layer, the first semiconductor layers, and the third semiconductor layers.

10. The method of claim 9, wherein the semiconductor metal oxide comprises an alkaline earth titanate selected from the group consisting of strontium titanate (SrTiO₃), barium titanate (BaTiO₃), barium strontium titanate (BaSrTiO₃), and lanthanum titanate (LaTiO₃).

11. The method of claim 9, wherein removing the sacrificial layer comprises using a fluoride-based etchant.

12. The method of claim 9, further comprising:
forming dielectric spacers in cavities formed by removing edge portions of the second and fourth semiconductor layers, wherein the dielectric spacers and the isolation layer comprise the same dielectric material.

13. The method of claim 9, wherein the sacrificial layer is formed by a molecular beam epitaxy (MBE) process at a temperature range of about 400 degrees Celsius to about 800 degrees Celsius.

14. The method of claim 9, further comprising:
removing the sacrificial gate structure and the second and fourth semiconductor layers to expose portions of the first and third semiconductor layers;
forming an interfacial layer on the exposed portions of the first and third semiconductor layers; and
forming a high-k dielectric layer over the interfacial layer and the isolation layer.

15. The method of claim 14, further comprising:
forming a first gate electrode layer surrounding the first semiconductor layers; and forming a second gate electrode layer surrounding the third semiconductor layers, wherein the first and second gate electrode layers comprise different conductive materials.

16. A method for forming a semiconductor device structure, comprising:
forming a plurality of fin structures from a substrate, each fin structure comprising a plurality of first semiconductor layers and a plurality of second semiconductor layers alternatingly stacked;
forming a sacrificial layer comprising a semiconductor metal oxide between two immediately adjacent first semiconductor layers;
diffusing metal elements from the sacrificial layer into the first semiconductor layers immediately adjacent to the sacrificial layer;
replacing the sacrificial layer with a dielectric material to form an isolation layer; and
forming a first source/drain feature and a second source/drain feature, wherein the first source/drain feature is in contact with a lower portion of the isolation layer and the first semiconductor layers below the isolation layer, and the second source/drain feature is in contact with an upper portion of the isolation layer and the first semiconductor layers above the isolation layer.

17. The method of claim 16, wherein the semiconductor metal oxide comprises an alkaline earth titanate, and the metal elements comprise strontium (Sr) or titanium (Ti).

18. The method of claim 16, wherein the first semiconductor layers immediately adjacent to the isolation layer have a gradient profile of the metal elements, with a higher concentration at an interface with the isolation layer than at a center region.

19. The method of claim 16, further comprising:
forming a dielectric material between the first and second source/drain features, wherein the dielectric material is recessed to a level below the first semiconductor layers above the isolation layer.

20. The method of claim 16, wherein replacing the sacrificial layer comprises selectively etching the sacrificial layer using a hydrogen fluoride-based etchant without substantially affecting the first and second semiconductor layers.
